(19) United States
(12) Patent Application Publication
(10) Pub. No.: US 2009/0166639 A1
(43) Pub. Date: Jul. 2, 2009

(54) ACTIVE FIELD EMISSION SUBSTRATE AND ACTIVE FIELD EMISSION DISPLAY

(75) Inventors: Tzung-Han Yang, Taipei (TW); Yen-Jung Lin, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: TATUNG COMPANY, Taipei (TW)

(21) Appl. No.: 12/036,280

(22) Filed: Feb. 24, 2008

(30) Foreign Application Priority Data
Dec. 28, 2007 (TW) 96151037

(51) Int. Cl. H01L 33/00

(52) U.S. Cl. 257/72; 257/E33.001

(57) ABSTRACT

An active field emission substrate including a thin film transistor (TFT) substrate and a field emission device substrate is provided. The TFT substrate has a plurality of TFTs, and each TFT at least includes a source, a drain, and a gate. The field emission device substrate is disposed on the TFT substrate and has a plurality of conductive channels and a plurality of field emission sources. Each conductive channel passes through the field emission device substrate and is electrically connected with each field emission source. Moreover, each conductive channel in the field emission device substrate is electrically conducted with the source or the drain of each TFT in the TFT substrate. The active field emission substrate is made up of two substrates fabricated by separate processes, so the procedures can be simplified and the yield can be improved.

### CROSS-REFERENCE TO RELATED APPLICATION

This application claims the priority benefit of Taiwan application serial no. 96151037, filed on Dec. 28, 2007. The entirety of the above-mentioned patent application is hereby incorporated by reference herein and made a part of this specification.

### BACKGROUND OF THE INVENTION

1. Field of the Invention

The present invention generally relates to a field emission display technology, in particular, to an active field emission substrate and an active field emission display.

2. Description of Related Art

Display devices are playing an increasingly important role in people's daily life. Computers, TVs, mobile phones, PDAs, digital cameras etc., all transmit information by controlling display devices. Contrary to the conventional Cathode Ray Tube displays, the latest-generation panel displays are advantageous in that they are light, compact, and health-friendly.

Among various technologies for panel display devices, field emission displays (FED) boast not only great graphic qualities as found in conventional Cathode Ray Tube displays, but also high luminous efficiency, short response time, good display coordination performance, high brightness, slim and light structure, wide viewing angle, broad range of working temperature, and high acting efficiency, contrary to Liquid Crystal Displays (LCD) which are problematic in narrow viewing angle, narrow working temperature range, and short response time. Besides, FEDs do not require backlight modules, they can provide superior brightness even when used in sunlight. Therefore, the current field emission displays has been regarded as a new display technology that is competitive against the LCD technology and even replace the LCD technology.

Currently, the FEDs are substantially classified into passive FEDs and active FEDs. The active FEDs accurately control the quantity of electrons hitting an anode through the current control, thereby further improving the stability of the display state. For example, ROC Patent NO. TW 480511 has disclosed an active FED having thin film transistors (TFT), as shown in FIG. 1.

In FIG. 1, a field emission array 100 is disposed on TFTs 104 located on a glass substrate 102. Each of the TFTs 104 has a source 106, a drain 108, and a gate 110, and an isolation layer 112 is plated on the TFTs 104. Carbon nanotubes 114 grow on a surface of the isolation layer 112, and each group of carbon nanotubes 114 is connected to the corresponding drain 108 through a via 116.

However, in the conventional active FED, the control circuit, the field emission substrate, and other elements must be fabricated through a semiconductor process, which causes a high fabrication cost and a low yield of the active FEDs.

### SUMMARY OF THE INVENTION

Accordingly, the present invention is directed to an active field emission substrate.

The present invention is further directed to an active FED, so as to solve the problems of high fabrication cost and low yield in the conventional active FED.

The present invention provides an active field emission substrate including a thin film transistor (TFT) substrate and a field emission device substrate. The TFT substrate has a plurality of TFTs, and each of the TFTs at least includes a source, a drain, and a gate. The field emission device substrate is disposed on the TFT substrate and has a plurality of conductive channels and a plurality of field emission sources. Each conductive channel passes through the field emission device substrate and is electrically connected with each field emission source. Moreover, each conductive channel of the field emission device substrate is electrically conducted with the source or the drain of each TFT in the TFT substrate.

The present invention further provides an active field emission display (FED) including an anode substrate and a cathode substrate arranged corresponding to the anode substrate. Moreover, the cathode substrate includes a TFT substrate and a field emission device substrate. The TFT substrate has a plurality of TFTs, and each of the TFTs at least includes a source, a drain, and a gate. The field emission device substrate is disposed on the TFT substrate, and has a plurality of conductive channels and a plurality of field emission sources. Each conductive channel passes through the field emission device substrate and is electrically connected with each field emission source. Moreover, each conductive channel of the field emission device substrate is electrically conducted with the source or the drain of each TFT in the TFT substrate.

In an embodiment of the present invention, the anode substrate includes an anode layer and a fluorescent layer. The fluorescent layer is disposed on the anode layer at a surface facing the cathode substrate. The anode layer includes a transparent conductive layer (ITO).

In an embodiment of the present invention, a material of the conductive channel includes a thin film conductive material or a thick film conductive material such as gold, silver, aluminium, nickel, and copper.

In an embodiment of the present invention, a diameter of the conductive channel is approximately between 10 μm and 5 mm.

In an embodiment of the present invention, a material of the TFT substrate includes a glass substrate, a ceramic substrate, a plastic substrate, or a semiconductor substrate.

In an embodiment of the present invention, the TFT substrate further includes a plurality of pixel electrodes, and each pixel electrode is electrically connected with the drain of each TFT.

In an embodiment of the present invention, the drain of each TFT is electrically conducted with each channel of the field emission device substrate through the pixel electrode.

In an embodiment of the present invention, the TFTs in the TFT substrate include bottom-gate TFTs or a top-gate TFTs.

In an embodiment of the present invention, the TFT substrate further includes a plurality of scan lines connected to the gates of the TFTs and a plurality of data lines connected to the sources of the TFTs.

In an embodiment of the present invention, the field emission device substrate includes a glass substrate, a ceramic substrate, a plastic substrate, or a semiconductor substrate.

In an embodiment of the present invention, the field emission source includes a Spindt-type field emission source, a surface conduction electron-type field emission source, a ballistic electron surface emitting display-type field emission source, a graphite field emission source, or a carbon nanotube-type field emission source.

In the present invention, the active field emission substrate made up of the TFT substrate and the field emission device substrate fabricated by separate processes is adopted, and thus the yield of the TFT substrate and the field emission source only need to be taken into account separately. The field emission device substrate can be fabricated by various methods in addition to the semiconductor process, and thus the fabrication cost is reduced.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a conventional field emission display (FED) having thin film transistors (TFTs).

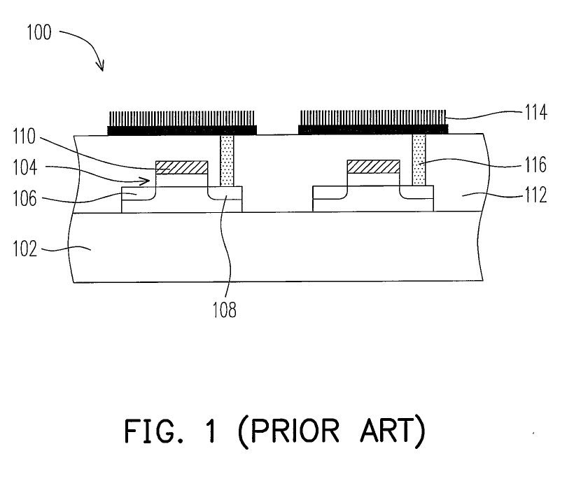

FIG. 2 is an exploded cross-sectional view of an active field emission substrate according to a first embodiment of the present invention.

FIG. 3 is an exploded cross-sectional view of an active field emission substrate according to a second embodiment of the present invention.

FIG. 4 is a circuit diagram of the TFT substrate in the second embodiment.

FIG. 5 is an exploded cross-sectional view of an active field emission substrate according to a third embodiment of the present invention.

FIG. 6 is a cross-sectional view of an active FED according to a fourth embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

The embodiments of the invention will be illustrated with reference to the accompanying drawings to make the present invention more apparent. However, the present invention can be practiced in various forms, but not limited to the embodiments of the present invention. In practice, the embodiments are provided for make the scope of the present invention more comprehensive to those of ordinary skill in the art. Moreover, in the drawings, dimensions and relative sizes of each layer and region are exaggerated for clarity.

Furthermore, the cross-sectional illustration is used to describe the embodiments of the present invention, and exemplifies the embodiments of the present invention. In other words, the shapes in the drawing may vary in accordance with fabrication technology and/or tolerance. Therefore, the embodiments of the present invention should not be explained to be limited to the specific shapes of region as shown in the drawings, but include shape deviations generated in the fabrication process.

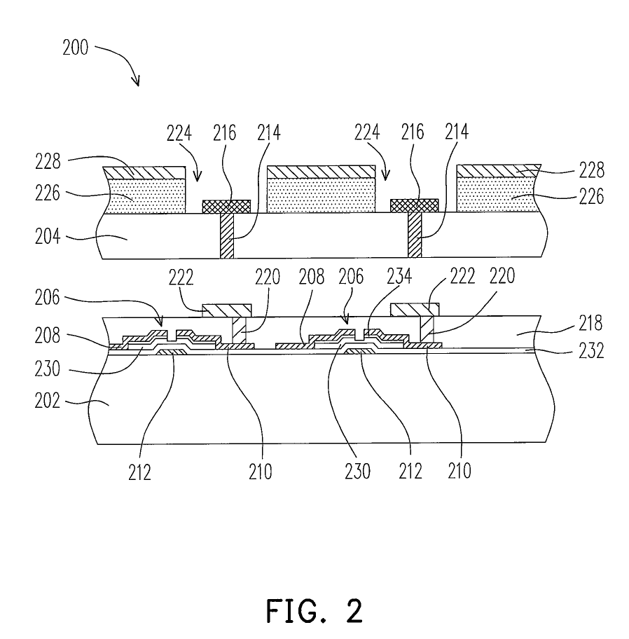

FIG. 2 is an exploded cross-sectional view of an active field emission substrate according to a first embodiment of the present invention.

Referring to FIG. 2, the active field emission substrate 200 of the first embodiment includes a TFT substrate 202 and a field emission device substrate 204. The field emission device substrate 204 is, for example, a glass substrate, a ceramic substrate, a plastic substrate, or a semiconductor substrate. The TFT substrate 202 has a plurality of TFTs 206. The material of the TFT substrate 202 is, for example, a glass substrate, a ceramic substrate, a plastic substrate, or a semiconductor substrate. Each TFT 206 at least includes a source 208, a drain 210, and a gate 212. For example, the TFTs 206 are bottom-gate TFTs. The field emission device substrate 204 is disposed on the TFT substrate 202, and has a plurality of conductive channels 214 and a plurality of field emission sources 216. Each conductive channel 214 passes through the field emission device substrate 204 and electrically connected with each field emission source 216. The material of the conductive channel 214 is, for example, a thin film conductive material or a thick film conductive material including gold, silver, aluminum, nickel, copper, or the like. Moreover, each conductive channel 214 of the field emission device substrate 204 is electrically conducted with the source 208 or the drain 210 of each TFT 206 in the TFT substrate 202. Further, the diameter of the conductive channel 214 is set, for example, between 10 μm and 5 mm according to requirements of sizes of the field emission sources 216, thickness of the field emission device substrate 204, and the like.

Referring to FIG. 2 again, in the first embodiment, the TFT substrate 202 is covered with an insulation layer 218, and is connected to pads 222 on a surface of the insulation layer 218 through contacts 220 in the insulation layer 218. In this manner, the conductive channels 214 of the field emission device substrate 204 are connected to the pads 222 by the existing technology, thus realizing the electrical conduction with one of the electrodes (i.e., the drains 210) of the TFTs 206. Furthermore, the TFT 206 in the first embodiment further includes a semiconductor layer 230 disposed between the source 208 and the gate 212 and between the drain 210 and the gate 212, a gate insulation layer 232 covering the gate 212, and an ohmic contact layer 234 disposed between the semiconductor layer 230 and the source 208 and between the semiconductor layer 230 and the drain 210. The field emission source 216 may be a Spindt-type field emission source, a surface conduction electron-type field emission source, a ballistic electron surface emitting display-type field emission source, a graphite field emission source, or a carbon nanotube-type field emission source. For example, in FIG. 2, the field emission source 216 is, for example, the carbon nanotube-type field emission source, and an insulation layer 226 having a plurality of openings 224 and a conductive layer 228 disposed on a surface of the insulation layer 226 are used in conjunction. The field emission sources 216 are disposed in the openings 224.

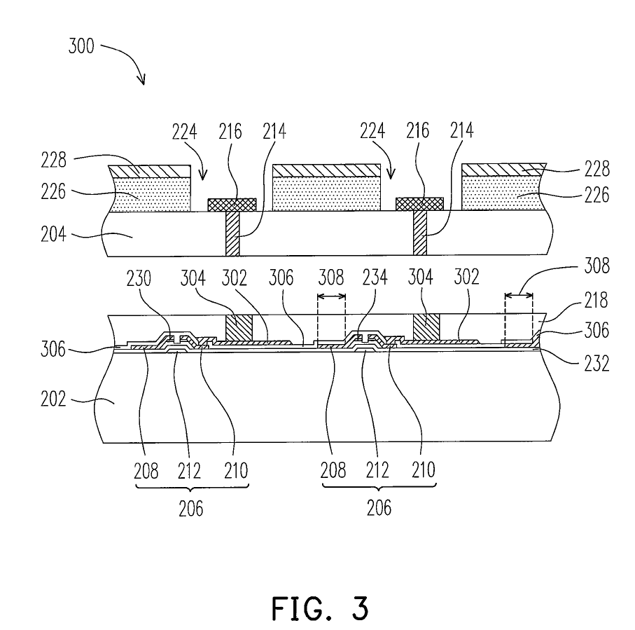

FIG. 3 is an exploded cross-sectional view of an active field emission substrate according to a second embodiment of the present invention. Like element numerals are used to indicate like elements in the first embodiment.

Referring to FIG. 3, the active field emission substrate 300 in the second embodiment differs from that in the first embodiment. A plurality of pixel electrodes 302 is disposed on the TFT substrate 202, and the pixel electrodes 302 are electrically connected with the drains 210 of the TFTs 206. Contacts 304 connected with the pixel electrodes 302 are disposed in the insulation layer 218, such that the conductive channels 214 in the field emission device substrate 204 are connected to the contacts 304 by the existing technology, thus realizing the electrical conduction with one of the electrodes (i.e., the drains 210) in the TFTs 206. Since the pixel electrodes 302 have larger areas, the alignment of the conductive channels 214 can be easily achieved. Moreover, a protective layer 306 is generally disposed between each pixel electrode 302 and each TFT 206.

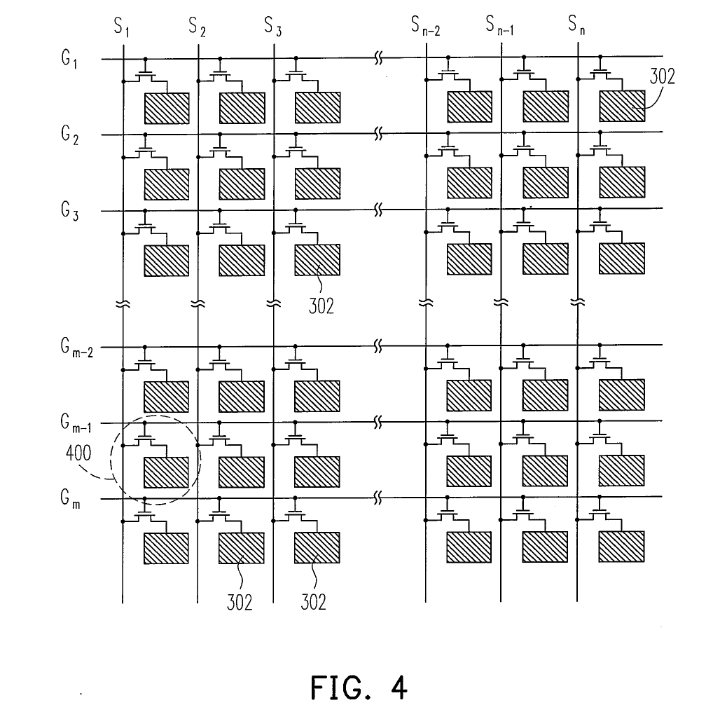

Further, the TFT substrate 202 of the second embodiment may adopt a large-size TFT to realize the fabrication of large-size field emission displays (FEDs), and the circuit diagram thereof is shown in FIG. 4. In FIG. 4, scan lines G₁, G₂, G₃ . . . Gₘ₋₂, Gₘ₋₁, Gₘ and data lines S₁, S₂, S₃ . . . Sₙ₋₂, Sₙ₋₁, Sₙ are shown. The scan lines G₁, G₂, G₃ . . . Gₘ₋₂, Gₘ₋₁, Gₘ are connected to the gates (e.g., the gates 212 in FIG. 3) of the TFTs, the data lines S₁, S₂, S₃ . . . Sₙ₋₂, Sₙ₋₁, Sₙ are connected to the sources (e.g., the sources 208 in FIG. 3) of the TFTs. Similar to FIG. 3, a plurality of pixel electrodes 302 is disposed in pixel electrode regions 400 divided by the scan lines G₁, G₂, G₃ . . . Gₘ₋₂, Gₘ₋₁, Gₘ and the data lines S₁, S₂, S₃ . . . Sₙ₋₂, Sₙ₋₁, Sₙ. Further, the data lines S₁, S₂, S₃ . . . Sₙ₋₂, Sₙ₋₁, Sₙ in FIG. 4 are equivalent to data lines 308 connected to the sources 208 in FIG. 3.

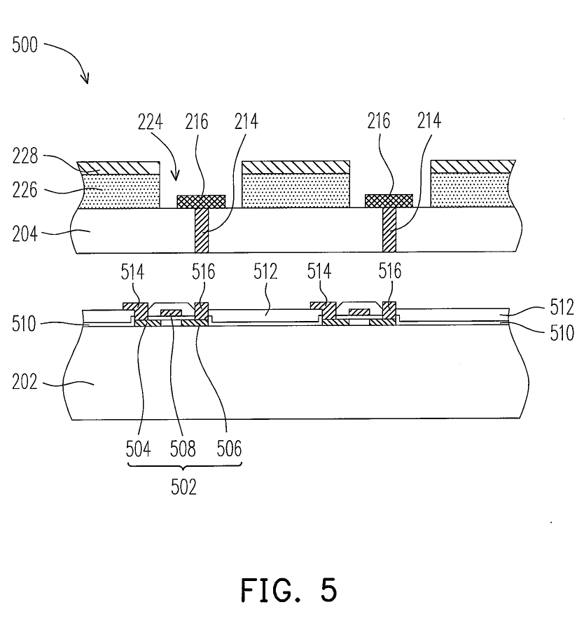

FIG. 5 is an exploded cross-sectional view of an active field emission substrate according to a third embodiment of the present invention. Like element numerals are used to indicate like elements in the first embodiment.

Referring to FIG. 5, the third embodiment differs from the first embodiment. TFTs 502 in the active field emission substrate 500 are top-gate TFTs. That is, a gate 508 of each TFT 502 is disposed on a source 504 and a drain 506, a gate insulation layer 510 is disposed between the source 504 and gate 508 and between the drain 506 and the gate 508, and a protective layer 512 covers the TFT 502. Further, a source contact 514 and a drain contact 516 respectively connected to the source 504 and the drain 506 are disposed in the protective layer 512. In this manner, the conductive channels 214 of the field emission device substrate 204 are connected to the drain contacts 516 by the existing technology, thus realizing the electrical conduction with one of the electrodes (i.e., the drains 506) of the TFTs 502.

Of course those persons skilled in ordinary art of the present invention can dispose pixel electrodes (not shown) on the TFT substrate 202 of FIG. 5 to electrically connect the drain contacts 516 of the TFTs 502, thus realizing the electrical conduction with the conductive channels 214 of the field emission device substrates 204 through the pixel electrodes, and thus the active field emission substrate of the present invention is not limited to that shown in FIG. 5.

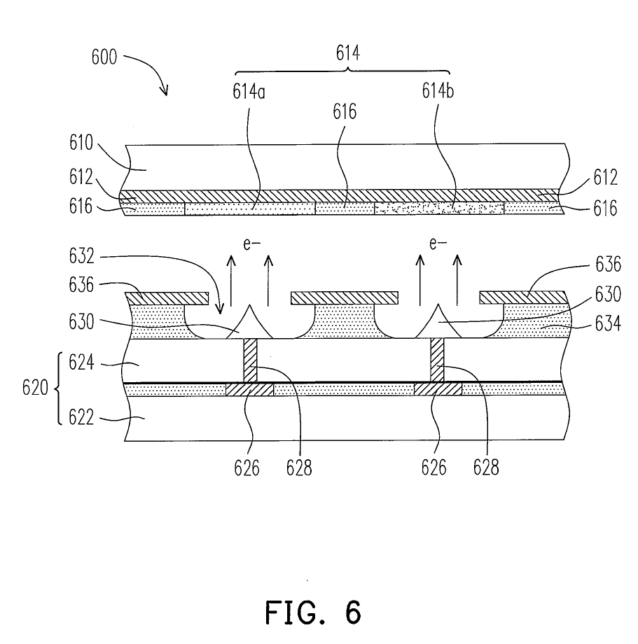

FIG. 6 is a cross-sectional view of an active FED according to a fourth embodiment of the present invention.

Referring to FIG. 6, the active FED 600 of the fourth embodiment includes an anode substrate 610 and a cathode substrate 620 arranged corresponding to the anode substrate 610. The cathode substrate 620 is constituted by a TFT substrate 622 and a field emission device substrate 624. In this embodiment, the TFT substrate 622 has a plurality of TFTs, and only one electrode 626 among the sources, drains, and gates of TFTs is shown in FIG. 6 for simplifying. Moreover, the TFTs in above embodiment can be used as the TFTs in the TFT substrate 622, and the details will not be described herein again. The field emission device substrate 624 is disposed on the TFT substrate 622, and has a plurality of conductive channels 628 and a plurality of field emission sources 630. Each conductive channel 628 passes through the field emission device substrate 624 and is electrically connected with each field emission source 630. The field emission source 630 is, for example, a Spindt-type field emission source, a surface conduction electron-type field emission source, a ballistic electron surface emitting display-type field emission source, a graphite field emission source, or a carbon nanotube-type field emission source. For example, in FIG. 6, the field emission source 630 is, for example, the Spindt-type field emission source, and an insulation layer 634 having a plurality of openings 632 and a conductive layer 636 disposed on a surface of the insulation layer 634 are used in the structure. The field emission sources 630 are disposed in the openings 632.

Referring to FIG. 6 again, each conductive channel 628 of the field emission device substrate 624 is further electrically conducted with one electrode 626 of the TFTs of the TFT substrate 622. Further, the diameter of the conductive channel 628 is, for example, between 10 μm and 5 mm in accordance with the requirements of size of the field emission sources 630, thickness of the field emission device substrate 624, and the like. For example, when the active FED 600 is used as a planar light source, the conductive channel 628 has a large diameter since the requirement on the definition is not high. Therefore, vias can be formed in the field emission device substrate 624 in advance through machining (e.g., drilling) or directly molding technique, and then the conductive channels 628 are formed through electroplating or screen printing and filling. However, when the active FED 600 serves as the display, a higher definition is required, the conductive channel 628 must have a small diameter, and a more precise method, for example, laser or etching process is used to form vias in advance, and then the sputtering, electroless plating, and electroplating processes are used to form the conductive channels 628. In addition, the conductive channels 628 can also be formed in other manners, which is not limited to the above processes.

Referring to FIG. 6 again, the anode substrate 610 in the fourth embodiment includes an anode layer 612 and a fluorescent layer 614. The anode layer 612 is, for example, a transparent conductive layer (ITO) or another transparent conductive material. The fluorescent layer 614 is disposed on the cathode substrate. 620 at a surface facing the anode layer 612, and fluorescent layers 614a, 614b of different colors may be optionally disposed according to practical requirements. In addition, a shielding layer 616 is disposed between the fluorescent layers 614a and 614b.

In view of the above, the active field emission substrate of the present invention is made up of the TFT substrate and the field emission device substrate fabricated by separate processes, so the procedures can be simplified and the yield can be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An active field emission substrate, comprising:
a thin film transistor (TFT) substrate, comprising a plurality of TFTs, wherein each TFT at least comprises a source, a drain, and a gate; and
a field emission device substrate, disposed on the TFT substrate, and comprising a plurality of conductive channels and a plurality of field emission sources, wherein each of the conductive channels passes through the field emission device substrate and is electrically connected with each field emission source, and
each conductive channel of the field emission device substrate is electrically conducted with the source or the drain of each TFT in the TFT substrate.

2. The active field emission substrate according to claim 1, wherein a material of the conductive channels comprises gold, silver, aluminium, nickel, or copper.

3. The active field emission substrate according to claim 1, wherein a material of the conductive channels comprises a thin film conductive material or a thick film conductive material.

4. The active field emission substrate according to claim 1, wherein a diameter of the conductive channels is between 10 μm and 5 mm.

5. The active field emission substrate according to claim 1, wherein the TFT substrate further comprises a plurality of pixel electrodes each electrically connected with the drain of each TFT.

6. The active field emission substrate according to claim 5, wherein the drain of each TFT is electrically conducted with each conductive channel of the field emission device substrate through each pixel electrode.

7. The active field emission substrate according to claim 1, wherein the TFTs in the TFT substrate comprise bottom-gate TFTs or top-gate TFTs.

8. The active field emission substrate according to claim 1, wherein the TFT substrate further comprises:
a plurality of scan lines, connected to the gates of the TFTs; and
a plurality of data lines, connected to the sources of the TFTs.

9. The active field emission substrate according to claim 1, wherein the field emission device substrate comprises a glass substrate, a ceramic substrate, a plastic substrate, or a semiconductor substrate.

10. The active field emission substrate according to claim 1, wherein the field emission source comprises a Spindt-type field emission source, a surface conduction electron-type field emission source, a ballistic electron surface emitting display-type field emission source, a graphite field emission source, or a carbon nanotube-type field emission source.

11. The active field emission substrate according to claim 1, wherein a material of the TFT substrate comprises a glass substrate, a ceramic substrate, a plastic substrate, or a semiconductor substrate.

12. An active field emission display (FED), comprising:
an anode substrate; and
a cathode substrate, arranged corresponding to the anode substrate, wherein the cathode substrate is the active field emission substrate according to claim 1.

13. The active FED according to claim 12, wherein a material of the conductive channels in the field emission device substrate comprises gold, silver, aluminium, nickel, or copper.

14. The active FED according to claim 12, wherein a material of the conductive channels in the field emission device substrate comprises a thin film conductive material or a thick film conductive material.

15. The active FED according to claim 12, wherein a diameter of the conductive channels in the field emission device substrate is between 10 μm and 5 mm.

16. The active FED according to claim 12, wherein the TFT substrate further comprises a plurality of pixel electrodes, and each pixel electrode is electrically connected with the drain of each TFT.

17. The active FED according to claim 16, wherein the drain of each TFT is electrically conducted with each conductive channel of the field emission device substrate through the pixel electrodes.

18. The active FED according to claim 12, wherein the TFTs in the TFT substrate comprise bottom-gate TFTs or top-gate TFTs.

19. The active FED according to claim 12, wherein the TFT substrate further comprises:
a plurality of scan lines, connected to the gates of the TFTs; and
a plurality of data lines, connected to the sources of the TFTs.

20. The active FED according to claim 12, wherein the field emission device substrate comprises a glass substrate, a ceramic substrate, a plastic substrate, or a semiconductor substrate.

21. The active FED according to claim 12, wherein the field emission source comprises a Spindt-type field emission source, a surface conduction electron-type field emission source, a ballistic electron surface emitting display-type field emission source, a graphite field emission source, or a carbon nanotube-type field emission source.

22. The active FED according to claim 12, wherein the anode substrate comprises:
an anode layer; and
a fluorescent layer, disposed on the anode layer at the surface facing the cathode substrate.

23. The active FED according to claim 22, wherein the anode layer comprises a transparent conductive layer.
